(19) United States
(12) Patent Application Publication
(10) Pub. No.: US 2006/0195288 A1
(43) Pub. Date: Aug. 31, 2006

(54) Method for at speed testing of multi-clock domain chips

(75) Inventors: Timothy G. McNamara, Fishkill, NY (US); Joseph E. Eckelman, Hopewell Junction, NY (US); William V. Huott, Holmes, NY (US)

Correspondence Address: RICHARD M. GOLDMAN, 371 ELAN VILLAGE LANE, SUITE 208, CA, 95134, US

(73) Assignee: International Business Machines Corporation

(21) Appl. No.: 11/056,874

(22) Filed: Feb. 12, 2005

(51) Int. Cl. G01R 27/28

(52) U.S. Cl. 702/118

(57) ABSTRACT

A method of and system for testing multi clock domain devices at functional clock speed by aligning the Launching C2 clocks of the high speed and low speed domains, issuing a Cl->C2 clock in each domain, to at speed test all intra-domain paths and the low speed to high speed paths; aligning the capturing C1 clock edges of the high speed and low speed clocks; and issuing a C2->C1 clock in each domain, to test the high speed to low speed paths.

### BACKGROUND

1. Field of the Invention

The invention relates to systems and methods for at speed testing of multi-clock domain chips.

2. Background Art

With each successive silicon chip technology, we continue to have the ability to put ever more functionality onto one chip. This is, frequently, functionality that had been spread over a plurality of separate chips. This capability is referred to as SOC (System On A Chip) design. For a variety of reasons, such as power loads, chip area, and performance trade-offs among others, many of these separate and distinct functions are designed to operate at different synchronous clock frequencies. For example, some functionalities on the chip could operate at some cycle time, n, while other functionalities may operate at cycle times n/2. n/3, etc.

Previously, for chip designs that had multi-frequency domains, the test methodology was to test each individual domain, individually, by itself, at that domain's frequency.

Testing the paths between domains was either done at a DC current, or with special generated or stored test patterns that targeted these domain crossings.

This was not altogether satisfactory. First, long test times were required since one test was required to be run for each clock domain in the series. Second, if DC testing was used, AC defects on the paths between domains would not be found, thus reducing the SPQL (Shipped Product Quality Level). Third, stored test patterns that targeted the domain crossing took time and effort to generate.

Thus, a clear need exists to provide a test system and method for at speed testing of multi-clock domain chips.

### SUMMARY

As described herein, one at speed testis performed to test all inter domain and intra domain paths at their corresponding functional frequencies. This reduces test time since it only requires one test, where all paths are tested at the same speed, thus the SPQL is at a higher level and no special stored patterns are required to be generated by the test engineers. In addition, the LBIST (Logic Built In Self Test) signature generated will match the DC signature generated by the test generation tools.

The method of and system of the invention tests multi clock domain devices at functional clock speed. This is done by first aligning the Launching C2 clocks of the high speed and low speed domains, issuing a C1->C2 clock in each domain. This is to at speed test all intra-domain paths and the low speed to high speed paths. The capturing C1 clock edges of the high speed and low speed clocks are aligned; a C2->C1 clock issued in each domain, to test the high speed to low speed paths

### THE FIGURES

FIG. 1 illustrates an example of two clock domains, one operating a hypothetical frequency of F1500, and the other operating at the one third slower frequency of F500.

FIG. 2 illustrates the clock sequences that are used to test all of the paths on a chip.

### DETAILED DESCRIPTION

The invention provides a method of and system for testing multi clock domain devices at functional clock speed. The first step is aligning the Launching C2 clocks of the high speed and low speed domains, and issuing a C1->C2 clock in each domain. This is done to at speed test all intra-domain paths and the low speed to high speed paths. Next the capturing C1 clock edges of the high speed and low speed clocks are aligned; and a C2->C1 clock issued in each domain, to test the high speed to low speed paths

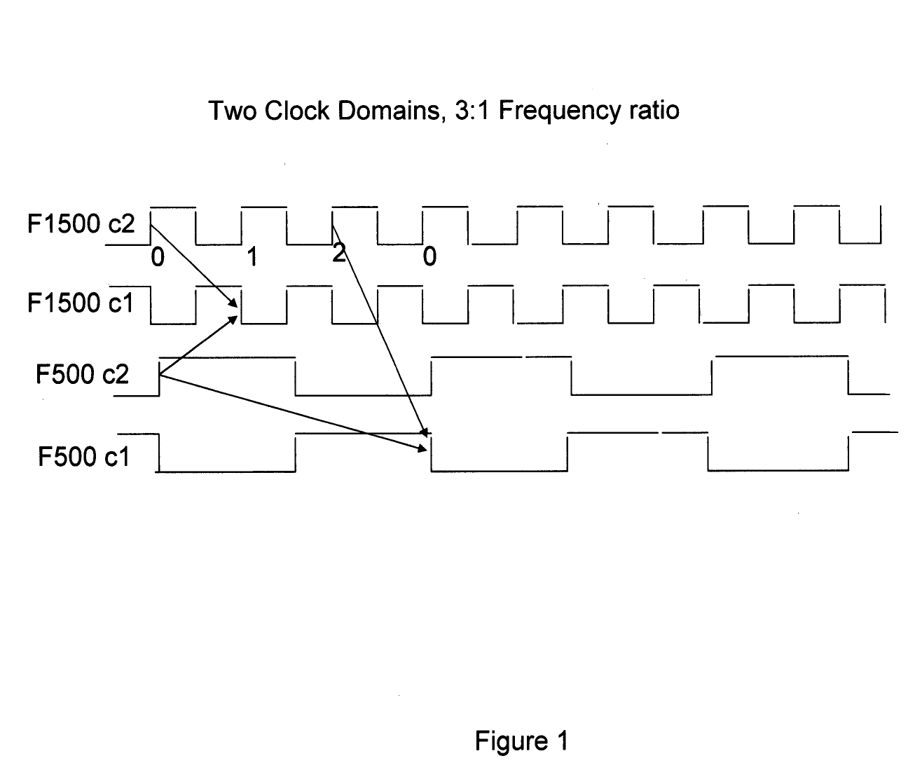

FIG. 1 shows an example of two clock domains, one operating at frequency F1500 and the other operating at the three times slower frequency of F500. FIG. 1 also illustrates the C1 and C2 clocks that are used in each of the clock domains. The arrows indicate the inter domain and intra domain paths. Note that all inter-domain crossing are times to operate at the fastest frequency, here shown as F1500.

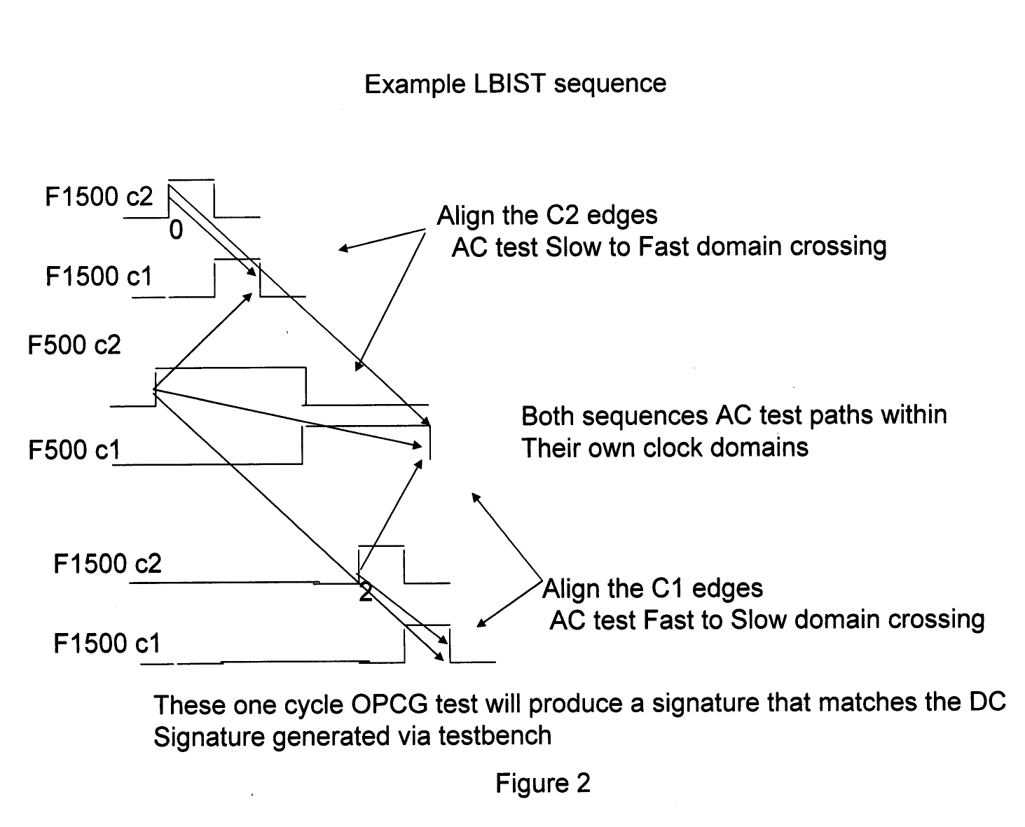

FIG. 2 shows the clock sequence that will be used to test all of the paths on the chip. The first sequence aligns the Launching C2 clocks of the F1500 and F500 domains. When we issue a C1->C2 clock in each domain, this at speed tests all intra-domain paths and the F500 to F1500 paths. The F1500 to F500 paths will be tested at the slower F500 frequency.

The second sequence that is run aligns the capturing C1 clock edges of the F1500 and F500 clocks. When we issue a C2->C1 clock in each domain, this will test the F1500 to F500 paths. The F500 to F1500 paths are tested at the slower F500 frequency.

Specifically, the method of the invention involves:
a) aligning the Launching C2 clocks of the high speed and low speed domains;
b) issuing a C1->C2 clock in each domain, to at speed test all intra-domain paths and the low speed to high speed paths;
c) aligning the capturing C1 clock edges of the high speed and low speed clocks; and
d) issuing a C2->C1 clock in each domain, to test the high speed to low speed paths.

To be noted is that the intra-domain paths are tested at the lower speed.

To be pointed out is that in both clock sequences, here illustrated as F500 and F1500, all paths are tested and hence the same signature is expected in both cases. It is also expected that this signature will match the simulated signature that a test generation tool would produce when clocking both of these domains at the same frequency. Therefore, the method and system described herein will allow both clock sequence to be produced with one LBIST (Logic Built In Self Tester) run, and that the combination of these sequences will test all of the paths on the chip at the operating frequency.

Thus, a further aspect of our invention is a multi-domain, multi-clock frequency chip having an LBIST to carry out the multi-domain, multi clock frequency method described herein

While our invention has been illustrated with only two clock domains, it is to be understood that the concept is readily extensible and scalable to chips having more then two clock domains and more then two clock frequencies.

We claim:

1. A method of testing multi clock domain devices at functional clock speed comprising the steps of:
a) aligning the Launching C2 clocks of the high speed and low speed domains;
b) issuing a C1->C2 clock in each domain, to at speed test all intra-domain paths and the low speed to high speed paths;
c) aligning the capturing C1 clock edges of the high speed and low speed clocks; and
d) issuing a C2->C1 clock in each domain, to test the high speed to low speed paths.

2. The method of claim 1 comprising testing all inter-domain paths at functional speed.

3. The method of claim 1 comprising testing all intra-domain paths at functional speed.

4. The method of claim 3 comprising testing intra-domain paths at the low speed clock speed.

5. A semiconductor chip having a plurality of multi-clock domain devices operating at different clock frequencies, and having a Logic Built In Self Tester adapted to test the multi clock domain devices at functional clock speed by the steps of:
a) aligning the Launching C2 clocks of the high speed and low speed domains;
b) issuing a C1->C2 clock in each domain, to at speed test all intra-domain paths and the low speed to high speed paths;
c) aligning the capturing C1 clock edges of the high speed and low speed clocks; and
d) issuing a C2->C1 clock in each domain, to test the high speed to low speed paths.

6. The semiconductor chip of claim 5 wherein said Logic Built In Self Tester tests all of the inter-domain paths at functional speed.

7. The semiconductor chip of claim 5 wherein said Logic Built In Self Tester tests all of the intra-domain paths at functional speed.

8. The semiconductor chip of claim 7 wherein said Logic Built In Self Tester tests the intra-domain paths at the low speed clock speed.
